(19) United States
(12) Patent Application Publication
(10) Pub. No.: US 2019/0131766 A1
(43) Pub. Date: May 2, 2019

(54) LASER MODULE WITH AN OPTICAL COMPONENT

(71) Applicant: OSRAM Opto Semiconductors GmbH, Regensburg (DE)

(72) Inventors: Roland Enzmann, Gelugor (MY); Markus Keidler, Pettendorf (DE); Josip Maric, Sinzing (DE); Peter Jander, Regensburg (DE)

(73) Assignee: OSRAM Opto Semiconductors GmbH, Regensburg (DE)

(21) Appl. No.: 16/095,426

(22) PCT Filed: Apr. 26, 2017
(86) PCT No.: PCT/EP2017/059989

§ 371 Date: Oct. 22, 2018

(30) Foreign Application Priority Data
Apr. 26, 2016 (DE) 10 2016 107 715.1

(51) Int. Cl. H01S 5/022; G02B 1/11; H01S 5/042

(52) U.S. Cl. CPC H01S 5/02292; H01S 5/0428; G02B 1/11; H01S 5/02296

(57) ABSTRACT

A laser module includes a housing with a cavity and a window opening, a side-emitting semiconductor laser diode, arranged in the cavity that emits light radiation in the form of a laser beam, an optical deflection structure that deflects the laser beam, emitted by the semiconductor laser diode, in a direction of the window opening, and an optical output coupling structure arranged in the region of the window opening to output couple the laser beam in a defined direction and/or with a defined emission profile, wherein the optical deflection structure and the optical output coupling structure are configured in one piece in the form of a shared optical component.

### TECHNICAL FIELD

This disclosure relates to a laser module having a housing and a side-emitting semiconductor laser diode arranged therein, a deflection structure that defects the laser beam and an optical output coupling structure which may be configured, for example, in the form of a diffractive optical element to form the laser beam or in the form of a Brewster window. The optical deflection structure and the optical output coupling structure are configured in one piece in the form of an optical component.

### BACKGROUND

Laser elements having semiconductor laser chips are used in various technical applications. In such laser elements, the laser chip is arranged in a housing that encapsulates the laser chip in a hermetically sealed manner to prevent premature aging of the laser facet of the laser chip. Further, the housing dissipates waste heat from the laser chip. Certain laser modules such as, e.g., modules with a pulsed laser for time-of-flight (TOF) applications, require a beam deflection and a diffractive optical element (DOE) to produce a top emitter, emitting perpendicular to the assembly plane, with a defined emission profile from an edge emitter emitting in the assembly plane. For the purposes of deflecting the laser beam, typical modules use a 45° prism made of glass, which needs to be arranged within the housing in a defined manner. A further element made of plastic or glass arranged in the region of the emission aperture of the laser beam from the module housing serves as a diffractive optical element. Consequently, production of such a laser module requires the assembly and precise alignment of two optical components, which is connected to a certain amount of outlay. Furthermore, the production of glass prisms is comparatively expensive.

Further, infrared laser radiation is used for different methods of measuring distance. In addition to time-of-flight (TOF) applications, these also include, inter alia, light detection and ranging (LIDAR) which, in vehicles, detects the surroundings, for example, and structured light (S-L), which scans three-dimensional objects and sets the focus in camera applications, for example. Increasingly, those measurement methods are also used in mobile applications such as smartphones or virtual reality (VR) headsets, for example. As a rule, laser diodes distinguished by particularly high efficiency are used as a laser light source. To simplify the handling during the assembly, such laser diodes are installed, as a rule, in a special housing (package). Depending on the respective application, specific requirements are placed on the package in the process. Thus, the package of the laser diode should be able to, as a rule, be processed together with other electronic components in a standard SMT process. Further, it should be possible to process the component without special knowledge of laser technology and without special precautions such as clean room conditions, for example. Moreover, emission of the laser beam should be effected in the direction of the surface normal of the assembly plane. Further, the package should have an installation height that is as low as possible and, in particular, does not exceed the installation height of other SMT electronics components arranged together with the laser diode on a printed circuit board. This applies all the more for mobile applications since only little installation space is available. Since a large beam diameter at the emission face is necessary, or at least desirable, for certain applications such as structured light, for example, the package should facilitate sufficient internal fanning of the laser beam. Since, as a rule, a low power uptake is desirable for mobile applications, the package should further have an electro-optic efficiency that is as high as possible. Finally, the package should be as cost-effective as possible and producible with a minimum number of process steps.

It could therefore be helpful to provide a laser module that satisfies the aforementioned issues and, moreover, can be produced relatively simply and cost-effectively.

### SUMMARY

We provide a laser module including a housing with a cavity and a window opening, a side-emitting semiconductor laser diode, arranged in the cavity that emits light radiation in the form of a laser beam, an optical deflection structure that deflects the laser beam, emitted by the semiconductor laser diode, in a direction of the window opening, and an optical output coupling structure arranged in the region of the window opening to output couple the laser beam in a defined direction and/or with a defined emission profile, wherein the optical deflection structure and the optical output coupling structure are configured in one piece in the form of a shared optical component.

We also provide an optical component for the laser module including a housing with a cavity and a window opening, a side-emitting semiconductor laser diode, arranged in the cavity that emits light radiation in the form of a laser beam, an optical deflection structure that deflects the laser beam, emitted by the semiconductor laser diode, in a direction of the window opening, and an optical output coupling structure arranged in the region of the window opening to output couple the laser beam in a defined direction and/or with a defined emission profile, wherein the optical deflection structure and the optical output coupling structure are configured in one piece in the form of a shared optical component.

### BRIEF DESCRIPTION OF THE DRAWINGS

FIG. 1 shows a laser module with a glass prism as a deflection element and a separately formed diffractive optical element.

FIG. 2 shows a laser module with an optical deflection structure and a diffractive optical element configured in the form of a shared optical component.

FIG. 3 shows a further laser module with an optical component, in which the optical deflection structure is provided with a special reflective coating.

FIG. 4 shows an optical component formed as a solid-type structure.

FIG. 5 shows an optical component formed as a hollow-type structure.

FIG. 6 shows a further laser module with an optical component formed as a hollow-type structure.

FIG. 7 shows a further laser module with an optical component formed as a hollow-type structure, in which the deflection of the laser beam is brought about by total internal reflection.

FIG. 8 shows a further laser module with a photodiode and a deactivation device that increases operational safety.

FIG. 9 shows, in an exemplary manner, an optical deflection structure with two reflection faces, at which the laser beam is deflected by total internal reflection.

FIG. 10 shows an optical deflection structure with only one reflection face and an input-side Brewster window.

FIG. 11 shows, in an exemplary manner, a possible design of the optical element with sidewalls for use on a PCB board.

FIG. 12 shows an optical deflection structure with an input-side refractive window that refracts the beam toward the desired emission direction.

FIG. 13 shows an optical component with a portion configured in the form of an optical waveguide.

FIG. 14 shows an optical component with a total of five reflection faces, with the aid of which the divergence axis of the laser beam is rotated.

FIG. 15 shows the optical component of FIG. 14, in a different perspective illustration.

FIG. 16 shows a perspective view of an optical component with a total of 3 reflection faces, input-side and output-side Brewster windows.

FIG. 17 shows the optical component of FIG. 16 in a different perspective view.

FIG. 18 shows the optical component of FIGS. 16 and 17 in a further perspective view.

FIG. 19 shows the optical component of FIGS. 16 to 18 in a further perspective view.

FIG. 20 shows a plan view of an optical component with an input-side Brewster window that elucidates the geometric conditions.

FIG. 21 shows a further laser module with an optical output coupling structure configured in the form of a Brewster window.

FIG. 22 shows a cross section through the laser module of FIG. 21.

### LIST OF REFERENCE SIGNS

100 Laser module
110 Housing
111 Cavity
112 Window opening
113 Mount for the semiconductor laser diode
114 Housing base
115 Window structure
116 Sidewalls of the window structure
120 Semiconductor laser diode
121 Emitting face of the semiconductor laser diode
122 Emission direction of the semiconductor laser diode
123 Emitted laser beam
124 Reflected laser beam
125 Beam-shaped laser beam
130 Optical deflection structure
131₁-131₅ Reflective faces
132 Reflective coating
133 Angle for total internal reflection
134 Waveguide structure
140 Diffractive optical element
141 Upper side
142 Lower side
143 Antireflection coating
150 Optical component
151 Input facet
152 Reflective coating
153 First sidewall
154 Second sidewall
155 Emission face
156 Input-side Brewster window
157 Output-side Brewster window
160 Photodiode
170 Control device
171 Driver circuit
172 Deactivation electronics

### DETAILED DESCRIPTION

Our laser module comprises a housing with a cavity and a window opening. A side-emitting semiconductor laser diode is arranged in the cavity to emit light radiation in the form of a laser beam. The laser module further comprises an optical deflection structure that deflects the laser beam emitted by the semiconductor laser diode, in the direction of the window opening and an optical output coupling structure, arranged in the region of the window opening, to output couple the laser beam in a defined direction and/or with a defined emission profile. The optical deflection structure and the optical output coupling structure are configured in one piece in the form of a shared optical component. The of the laser module is simplified by using a single optical component in place of two separate optical component parts. Further, only a single adjustment step is necessary when using a single optical component, as a result of which the production of the laser module is likewise simplified. Moreover, the tolerance chain also reduces in this case, which is noticeable, in particular, by way of an increase in the adjustment accuracy. Additionally, the optical component configured in one piece is substantially less susceptible to subsequently occurring loss of adjustment.

The optical output coupling structure may be configured in the form of a diffractive optical element to produce a laser beam with a defined emission profile. Such a diffractive optical element facilitates production of any light pattern in a simple and cost-effective manner.

The optical output coupling structure may be configured in the form of a Brewster window. Reflections of the laser radiation at optical interfaces can be reduced in a particularly simple manner with the aid of a diffractive window. As a result, it is possible, first, to increase the electro-optic efficiency of the optical component and, at the same time, increase the degree of polarization of the laser radiation, too.

The optical component may be configured in the form of a solid prism. Such a solid prism can be produced relatively easily in the process. Particularly when using an injection molding method of producing the solid prism, it is possible to dispense with complicated undercuts by which production methods of injection molded parts can be made more difficult.

The optical component may comprise an input facet facing the semiconductor laser diode, the input facet being equipped with an antireflection coating. As a result of this special arrangement of the input facet, reflections of the laser beam, which can possibly occur during the transition into the prism at the input facet, occur away from the diffractive optical element. As a result, an unwanted interaction of these laser beams reflected at the input facet with the laser radiation emerging in regular fashion from the laser module via the diffractive optical element is prevented. In contrast, power losses of the laser module can be reduced with the aid of the antireflection coating applied to the input facet.

The optical component may be configured to be hollow such that the optical deflection structure and the diffractive optical element connect to one another via sidewalls of the optical component. Such an optical component can be produced with less material outlay, and is accompanied by a reduction in the material costs. At the same time, the weight of the optical component is also reduced as a result of the hollow construction. Further, power and quality losses of the laser beam that occur when passing through the optical component can be reduced compared to an optical component configured to be constructed in solid fashion.

The diffractive optical element may be equipped with an antireflection coating on the input side. This antireflection coating facilitates improved input coupling of the laser beam into the part of the optical component serving as a diffractive optical element, wherein unwanted reflections of the laser beams can be avoided. Consequently, it is possible to obtain a higher output power of the laser module.

The optical deflection structure may comprise a face reflective for the light radiation emitted by the semiconductor laser diode. This achieves an ideal reflection of the laser beam to obtain a higher output power of the laser module.

The reflective face of the optical deflection structure may comprise a coating made of a metallic or dielectric material. By using such a reflective coating, it is possible to achieve an ideal reflection of the laser beam, even if the material of the optical component per se does not admit any suitable reflection. On account of the high reflectivity of metals, these materials are particularly well suited to the production of reflection layers.

The reflective face of the optical deflection structure may be arranged at an angle to the semiconductor laser diode at which the deflection of the laser beam, emitted by the semiconductor laser diode, is effected in the direction of the window opening, substantially by total internal reflection. A separate coating with reflective material can be dispensed with when exploiting total internal reflection to deflect the laser beam. Hence, it is possible to obtain a simpler and more cost-effective production.

The laser module may further comprise a photodiode arranged downstream of the optical deflection structure in the emission direction of the semiconductor laser diode, the photodiode monitoring the correct assembly position of the optical component in the housing. With the aid of such a photodiode, it is possible to detect both an incorrect assembly and subsequent slippage of the optical component in the module housing. Consequently, the operational safety of the laser module can be significantly increased, in particular in view of eye safety.

The laser module may further comprise deactivation electronics that deactivate the semiconductor laser diode as soon as the photodiode registers a deviation from the correct assembly position of the optical component. Consequently, such deactivation electronics facilitate an increased operational safety of the laser module. By arranging such deactivation electronics in the module housing, particularly fast and hence particularly effective deactivation of the semiconductor laser diode can be obtained. Consequently, this facilitates a particularly high operational safety of the laser module.

The laser module may further comprise a driver circuit to operate the semiconductor laser diode. Integrating the driver circuit into the laser module facilitates particularly compact construction of the laser module.

The driver circuit may be configured to operate the semiconductor laser diode in a pulsed mode of operation. Such a laser module is suitable, in particular, for different time-of-flight applications.

The optical component may be formed from a plastics material. Compared to a glass material in which bar and individual part processes are necessary, a plastics material facilitates a particularly simple and cost-effective production of the optical component.

The optical component may be configured in the form of an injection molded part. This production method facilitates a particularly simple and fast production of the optical component. Using this, it is possible to significantly reduce the production costs.

The optical deflection structure may comprise at least two reflection faces that deflect the laser beam. It is thus possible to obtain a targeted guidance of the laser beam within the optical deflection element. Moreover, the angle of reflection at the respective reflection faces can be reduced with the aid of a plurality of reflection faces, as a result of which formation of a total internal reflection is simplified. In particular, it is possible to use materials with a lower optical refractive index in the process. The use of a plurality of internal reflections further facilitates a targeted guidance of the laser beam within the optical deflection element, as a result of which certain beam shaping can be improved.

At least a part of the reflection faces may be configured to deflect the laser beam by total internal reflection. A beam deflection can be obtained with the aid of total internal reflection, even without an additional coating of the reflection face. This allows the production outlay and the production costs to be reduced.

The reflection faces may be arranged in relation to the laser beam, emitted by the laser diode such that a first divergence axis of the laser beam initially extending substantially perpendicular to an assembly plane is rotated to be substantially parallel to the assembly plane. Since the laser beam in side-emitting laser diodes has, as a rule, the greatest divergence in the vertical direction, it is possible overall to reduce the installation height of the optical deflection structure and hence of the overall laser module by rotating the divergence axis from the vertical into the horizontal. Further, this facilitates a longer guidance of the laser beam within the optical deflection structure for purposes of expanding the laser beam.

The optical deflection structure may comprise an input face to input couple the laser beam and an emission face to output couple the laser beam, wherein at least one of the faces is configured in the form of a Brewster window for the laser beam striking thereon. Reflections of the laser radiation at optical interfaces can be reduced in a particularly simple manner with the aid of the Brewster window. As a result, it is possible, first, to increase the electro-optic efficiency of the optical component and, at the same time, also increase the degree of polarization of the laser radiation.

The optical deflection structure may comprise an optical waveguide structure configured to guide the laser beam within the optical deflection structure by total internal reflection. The laser beam can be guided in a targeted manner within the optical deflection structure with the aid of the optical waveguide structure. In particular, this can be used to realize a particularly long path of the laser beam within the deflection structure, facilitating particularly great fanning of the laser beam.

The use of TIR mirrors facilitates a beam deflection into the surface normal of the assembly plane without the use of coated optical elements. Typically, such coated elements have to be assembled in a separate process step and, further, they are expensive to produce. By contrast, the optical component can be produced relatively easily and cost-effectively as an injection molded part made of plastic.

The Brewster windows reduce reflections at the surfaces and consequently increase the overall electric-to-optical efficiency of the laser module. Further, this achieves a reduction of possible stray radiation and a possible heat influx into the laser module by way of absorbed laser radiation. Since the Brewster effect occurs only for one direction of polarization, this can be used further to increase the degree of polarization of the laser light emitted from the laser module.

During the preferred assembly of the laser diodes, the axis of the maximum beam divergence is oriented in normal fashion in relation to the assembly face, leading to a technical contradiction between maximum beam diameter and minimum installation height. This contradiction can be resolved by way of the described tilt of the direction of maximum divergence of the laser beam. A large beam diameter of the laser beam with, at the same time, a small installation height of the laser module is thus possible.

There is no need to assemble a separate optical element as a result of integrating the optical component into the housing. This also dispenses with the necessity of maintaining suitable surfaces for the assembly. Consequently, the substrate may be embodied in a more cost-effective manner. In contrast to conventional approaches, only one component need be assembled, the component unifying a plurality of functions, namely a hermetically sealed, or at least dust-tight, housing, a suitable surface as an attachment point for assembly tools such as the pick & place tool, for example, a beam deflection, a beam expansion and an emission window. As a result, the number of parts to be assembled is reduced, which is accompanied by a corresponding reduction in the process steps.

The above-described properties, features and advantages and the manner in which these are achieved will become clearer and more easily understandable in conjunction with the following description of examples explained in more detail in conjunction with the drawings.

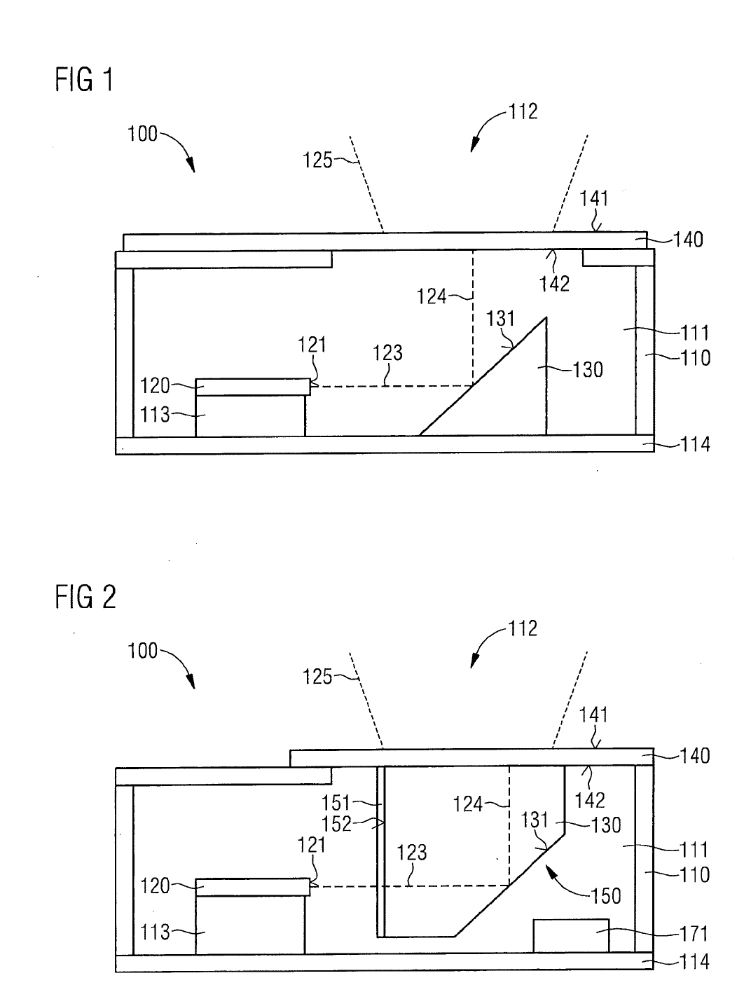

FIG. 1 shows a typical laser module 100 with a housing 110 and a side-emitting semiconductor laser diode 120 arranged in a cavity 111 of the housing 110. The module housing 110 comprises a housing base 114, which can be configured in the form of a circuit board, for example, sidewalls and a covering plate with a window opening 112. The window opening 112 is sealed by a component 140 embodied as a diffractive optical element (DOE). Typically, the diffractive optical element is a carrier made of a transparent material such as glass or plastic, for example, on the upper or lower side 141, 142 of which specifically configured microstructures are arranged. The microstructures produce a defined interference pattern from an incident laser beam by phase modulation, the intensity distribution of the interference pattern forming the desired emission profile of the laser beam emitted from the module housing. Further, a prism 130 with a reflective face 131 and serving as an optical deflection element is arranged within the cavity 111. The semiconductor laser diode 120 arranged on a mount substantially parallel to the housing base 114 emits defined light radiation in the form of a focused laser beam 123 in a lateral direction via a lateral face 121. The laser beam 123 directed onto the optical deflection element 130 is deflected in the direction of the window region 112 at the reflective face 131. The reflected laser beam 124 is converted by the diffractive optical element 140 into a laser beam 125 that depends on the respective application. As further shown in FIG. 1, the optical deflection structure 130 and the diffractive optical element 140 are formed as separate components, each requiring a dedicated assembly and adjustment step. Since both elements have to be adjusted separately, maladjustments of the optical component parts may arise particularly easily on account of the longer tolerance chain and adjustment errors of the individual optical components.

FIG. 2 shows an improved laser module in which the optical deflection structure 130 and the diffractive optical element 140 are configured in one piece in the form of a shared optical component 150. On account of the common production, the optical deflection structure 130 and the diffractive optical element 140 are already ideally adjusted in relation to one another in such an optical component. For this reason, only a single adjustment step is still necessary, within the scope of which the optical component 150 is aligned relative to the semiconductor laser diode 120, after or during the assembly in the housing 110.

Assembly of the laser module 100 is also simplified by the integral example of the optical component 150 since only a single component still has to be fastened in or at the housing 110.

The optical component 150 is preferably produced from a plastics material. By using cost-effective plastics materials, it is possible to significantly reduce production costs in relation to a deflection prism typically formed of glass. Polycarbonate, for example, is suitable as a plastic for the optical component 150. However, any suitable transparent plastic can be used as a material for the optical component 150.

The use of plastic further facilitates production of the optical component 150 in the form of an injection molded part. With the aid of this method, it is possible to significantly reduce the production costs, particularly compared to the complicated production processes of glass prisms.

As in the example of FIG. 2, the optical component 150 can be solid in the form of a solid prism. Alternatively, the optical component 150 can also be produced in the form of a hollow prism only consisting of sidewalls. In the solid construction type, the laser beam 123 emitted laterally by the semiconductor laser diode 120 enters into the optical component 150 via an input facet 152 facing the emission face 121 of the laser diode 120. The input facet 152 can be equipped with a suitable antireflection coating 151 for the purposes of minimizing reflection losses. In the optical component 150, the laser beam 123 strikes the optical deflection structure 130, which is configured in the form of a reflective face 131 in this example. Inclination of the reflective face 131 is substantially 45°, and the laser beam 123 striking thereon is reflected substantially perpendicularly upwardly in the direction of the diffractive optical element 140. However, in principle, the angle of inclination of the reflective face 131 may also deviate from 45°, depending on the respective subsequent application. Finally, the diffractive optical element 140 forming the upper part of the optical component 150 reshapes the reflected laser beam 124 striking thereon into an emission laser beam 125 with the defined emission profile. The required microstructures can be arranged on the upper side 141 of the diffractive optical element 140, for example.

As is further clear from FIG. 2, the compact laser module 100 may further also already comprise the driver circuit 171 to operate the semiconductor laser diode 120. This simplifies the assembly of the laser module since no external driver circuit is required. Further, a particularly fast and accurate control of the semiconductor laser diode 120 is facilitated by the direct vicinity of the driver circuit 171 in relation to the semiconductor diode 120, as is required, in particular, for time-of-flight applications.

In the example shown here, the driver circuit 171 is arranged underneath the optical component 150. However, in principle, corresponding electronics can be arranged at any suitable point within the cavity 111 such as in the vicinity of the semiconductor laser diode 120, for example.

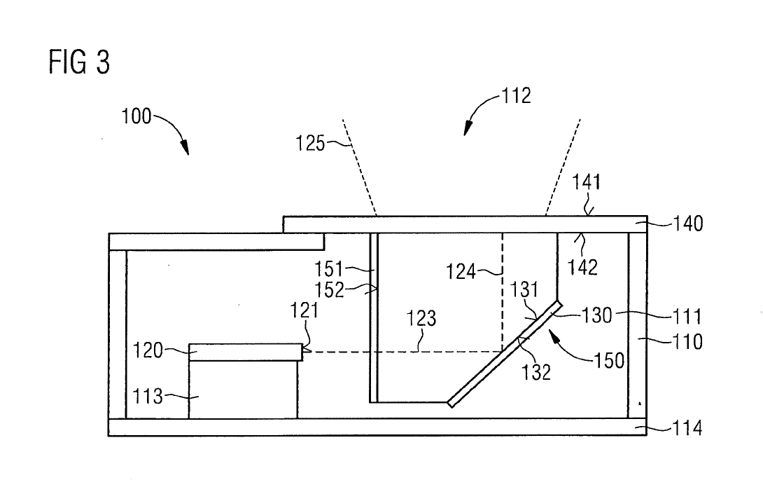

To ensure sufficient reflectivity of the optical deflection structure 130, the reflective face 131 can be equipped with a reflective coating 132. The reflective coating 132 may consist of any suitable material such as a metal or a dielectric material, for example. A mixture of a plurality of these materials is also possible. In particular, the reflective coating may comprise a layer stack, the thickness and layer sequence of which are matched to the respective wavelength of the emitted laser radiation. An example of the optical component 150 with such a reflective coating 132 is shown in FIG. 3 by way of example.

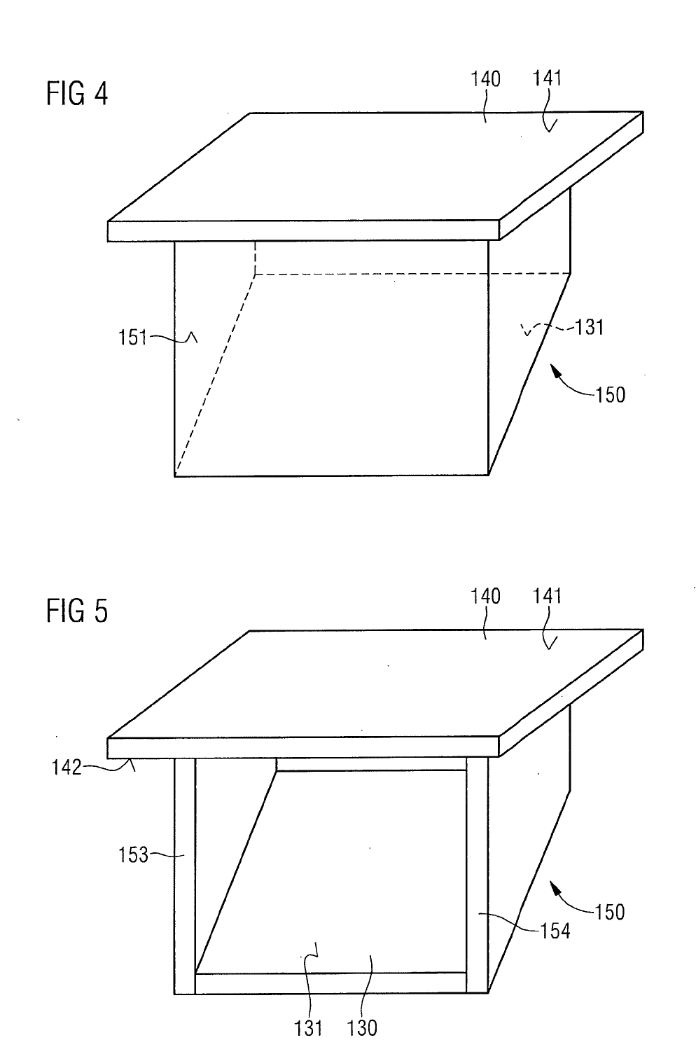

FIGS. 4 and 5 elucidate the structure of the two basic examples of the optical component 150. FIG. 4 shows a perspective view of an optical component 150 produced as a solid-type structure in which the volume between the diffractive optical element 140 and the optical deflection structure 130 is configured in the form of a solid prism. The reflective face 131 is formed by a facet of the solid prism. The optical component 150 further comprises an input-side facet 151. This input facet can be equipped with an antireflection coating (not shown here).

In contrast, FIG. 5 shows an optical component 150 configured as a hollow-type structure configured in the form of a hollow prism. The diffractive optical element 140 and the optical deflection structure 130 are separated from one another by a cavity and merely connected to one another by way of the sidewalls 153, 154 of the optical component 150. The reflective surface 131 preferably forms the inner side of the optical deflection structure 130 facing the cavity. This structure facilitates the arrangement of the microstructures both on the upper side 141 of the diffractive optical element 140 and on the lower side 142 thereof.

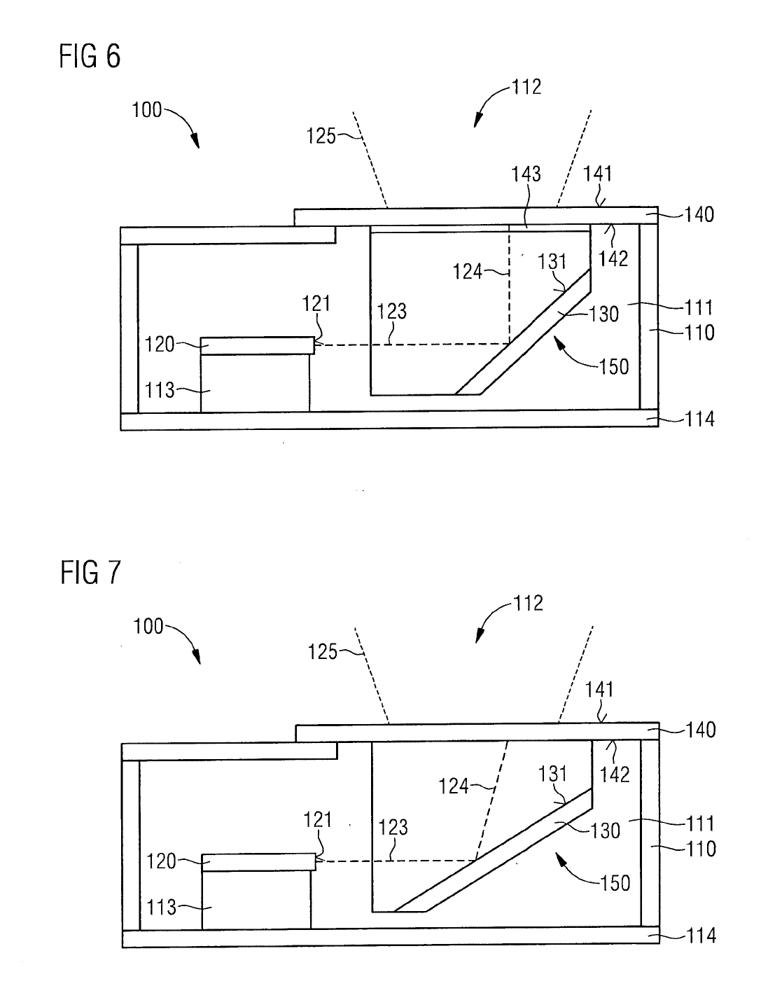

FIG. 6 shows a side view of a further example of the laser module 100 with an optical component 150 configured in analogous fashion to the component from FIG. 5 with a hollow-type structure. As is clear from FIG. 6, the reflection preferably occurs at the side 131 of the optical deflection element 130 facing the cavity. The reflective face 131 of the optical deflection structure 130 can further have a reflection layer that increases reflectivity for the respectively employed light wavelength. This reflection layer can be formed from any suitable material such as a metal or a dielectric, for example. Further, the reflection layer can also be configured in the form of a layer stack made of a plurality of suitable materials.

An appropriate antireflection coating 143 can be arranged on the lower side 142 of the diffractive optical element 140 to reduce possible reflection losses of the laser radiation when the reflected laser beam 124 strikes the diffractive optical element 140. The microstructures for beam shaping can be arranged both on the upper side 141 and on the lower side 142 of the diffractive optical element 140.

A deflection of the emitted laser beam 123 can also be effected by exploiting total internal reflection, which occurs under certain conditions at material boundaries of different optical density. To this end, FIG. 7 shows a further example of a laser module with an appropriately formed optical component 150. The reflective face 131 of the optical deflection structure 130 is arranged at an angle of total internal reflection that deviates from 45°. The angle of total internal reflection depends substantially on the material of the optical deflection structure 130 and the employed light wavelength. By way of example, in an optical component 150 formed from polycarbonate, total internal reflection occurs at an angle of approximately 38°, for example. Consequently, the optical deflection structure 130 formed from polycarbonate should be arranged such that the laser beam 123 emitted by the semiconductor laser diode 120 strikes the optical deflection structure 130 at an angle of approximately 38°.

Using total internal reflection to deflect the laser beam 123 facilitates a particularly simple and cost-effective production since it is possible in this case to dispense with special coating required on the reflective face 131. As shown in the example of FIG. 7, a change in the angle of inclination of the optical deflection structure in relation to the principal axes of the module is also accompanied by a change in the angle and the position of the reflected laser beam 124 that strikes the diffractive optical element 140. For the purposes of compensating for this effect, the diffractive optical element 150 or the microstructures thereof that bring about the beam shaping can be adapted accordingly or arranged in a displaced manner. Moreover, deviation of the angle of the reflected laser beam 124 from the perpendicular can be reduced as desired by changing the assembly angle of the semiconductor laser diode 120 and appropriately tilting the optical deflection structure 130 (not shown here).

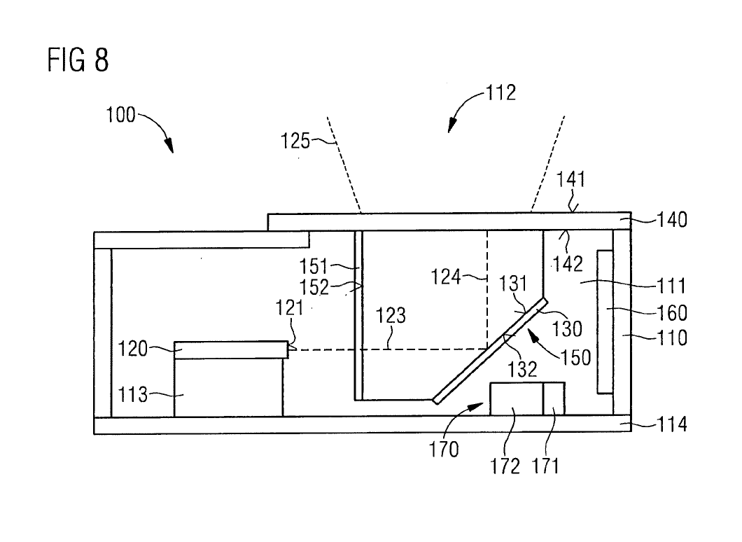

Since the operational safety and, in particular, the eye safety for the user are no longer ensured if the optical component 150 is incorrectly assembled in the module housing 110 or if the optical component 150 subsequently slips or falls out of the module housing 110, it may be expedient or necessary to provide suitable safety measures in the laser module 100. To this end, the laser module 100 can be equipped with, e.g., a photodiode 160 that monitors the correct assembly position of the optical component 150, the photodiode being arranged at a suitable position within the module housing 110. As shown in FIG. 8, the photodiode 160, in this case, may be arranged along the optical axis of the laser beam 123 emitted by the semiconductor laser diode 120, behind the optical deflection structure 130, for example. Should a situation in which the photodiode 160 receives laser radiation from the semiconductor laser diode 120 occur during operation of the laser module 100, the assumption can be made that an incorrect assembly of the optical component 150 is present or that the optical component 150 has slipped or fallen out of the module housing 110. In this case, a suitable protective circuit can immediately curtail operation of the semiconductor laser diode 120. Corresponding deactivation electronics 172 can be likewise housed in the module housing 110. In the example shown in FIG. 8, the deactivation electronics 172 are part of a common control device 170 likewise comprising the driver circuit 171 of the semiconductor laser diode 120. The driver circuit 171 and the deactivation electronics 172 can also be configured in a structurally unified manner, as a result of which there are particularly low spatial requirements for the control device 170. Further, a particularly fast deactivation of the semiconductor laser diode in a suddenly occurring fault is possible should the deactivation electronics 172 be arranged in the direct vicinity of the driver circuit 171. However, in principle, the driver circuit 171 and the deactivation electronics 172 can also be configured as separate devices, which can be housed at different locations within and outside of the module housing 110.

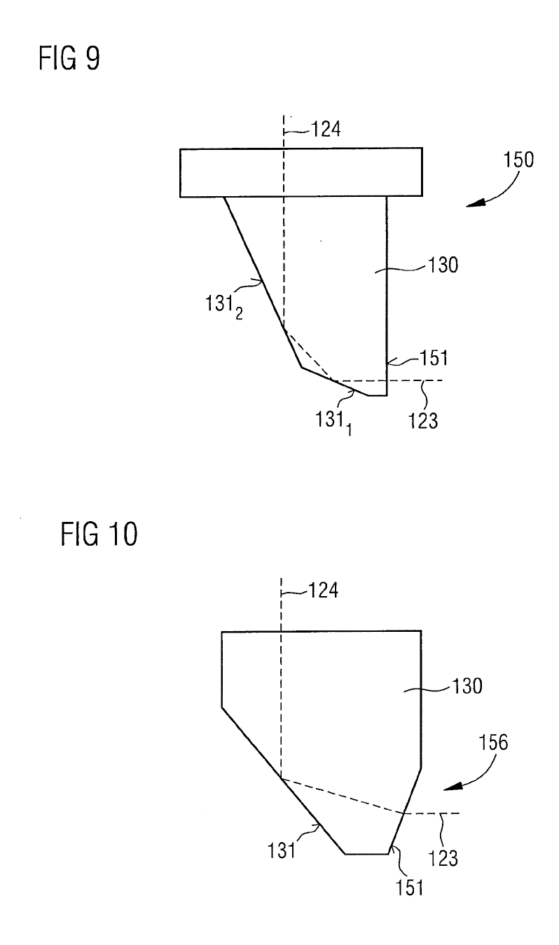

To this end, FIG. 9 shows an optical component 150 with an appropriate optical deflection structure 130 comprising two reflection faces 131₁, 131₂ that deflect the laser beam. The two reflection faces 131₁, 131₂ are each arranged such that the laser beam 123 strikes thereon at a relatively flat angle in each case, which at most corresponds to the critical angle of the total internal reflection. In this case, this critical angle depends on the ratio of the refractive indices of the two optical media, namely of the material of the optical deflection structure 130 and the surrounding gas volume. As is clear from FIG. 9, the laser beam 123 is deflected from a horizontal direction extending substantially parallel to the assembly plane into a vertical direction extending parallel to the surface normal of the assembly plane after two instances of total internal reflection at the two reflection faces 131₁, 131₂.

As is clear from FIG. 10, deflection of the laser beam 123 into a vertical direction can also be effected with only one instance of total internal reflection instead of two instances of total internal reflection. Upon the entry into the optical deflection structure 130, the laser beam 123 is already refracted in the direction of the surface normal of the assembly plane by an input face 151 tilted in relation to the vertical so that it strikes the only reflection face 131 at a flatter angle. The input face 151 is preferably tilted by a certain angle such that the input face 151 forms an input-side refractive window. If this angle corresponds to a Brewster angle, the input face 151 forms a corresponding Brewster window 156, by which the reflection of the laser radiation 123 of a certain polarization direction is suppressed. This results in improved input coupling for this polarization direction, in turn leading to an improved electro-optic efficiency.

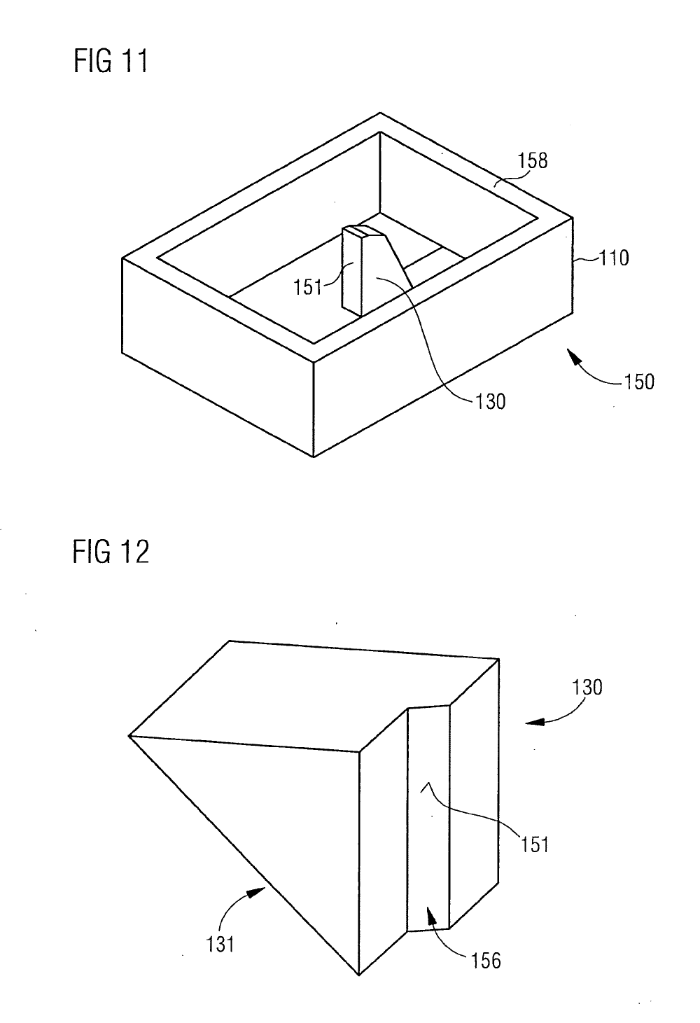

FIG. 11 shows a possible integration of the optical deflection element 130 from FIG. 9 into an optical component 150 configured in the form of a housing lid. The optical component 150 also comprises sidewalls 158, the sidewalls, at least in part, defining a housing surrounding the laser diode. However, as a rule, the optical component 150 is only configured as an element closing off a window opening within an already existing housing.

FIG. 12 shows a further optical deflection structure 130 comprising an input-side refractive window 156. The refractive window 156 is formed by the input face 151 having a tilt about a vertical axis in a central portion. In this arrangement, the laser beam 123 is refracted not into a vertical, but into a horizontal direction. In this arrangement, too, the input face 151 can be a Brewster window if an appropriate Brewster angle is chosen.

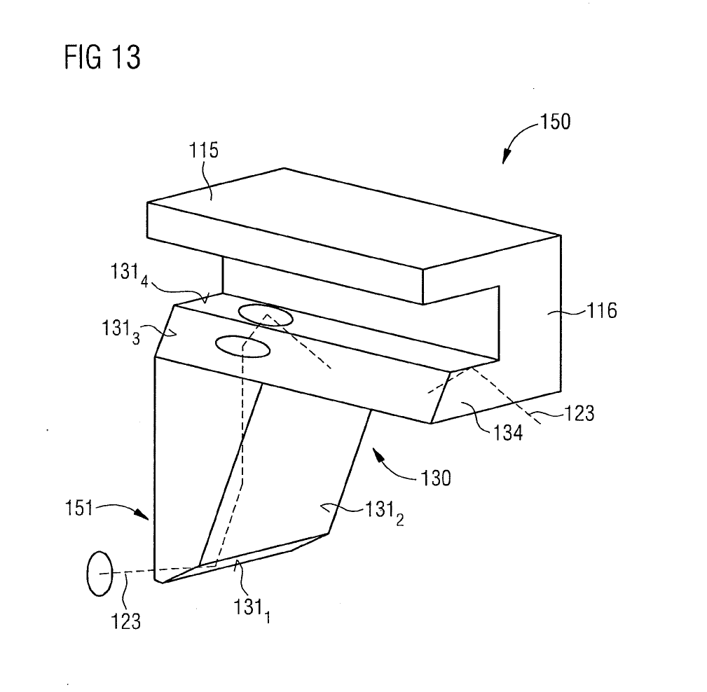

FIG. 13 shows a further optical component 150, in which the laser beam 123 is reflected back and forth within the deflection structure 130 by internal reflections at a plurality of internal reflection faces 131₁, 131₂, 131₃, 131₄, until the desired alignment and/or expansion of the laser beam 123 is reached. The lower portion of the optical deflection structure 130 in this case corresponds to the prism from FIG. 9, by which there is a deflection of the laser beam into a substantially perpendicular direction. In contrast, the upper portion 134 of the optical deflection structure 130 is configured in the form of an optical waveguide in which the laser beam 123 is substantially guided in a horizontal direction parallel to the assembly plane by way of a plurality of successive reflections. Subsequently, the laser beam 123 is likewise output coupled from the optical component 150 by way of one or more reflections, although this is not shown here for reasons of clarity. Further, it is clear from FIG. 13 that the optical component 150 can also be configured in integral form with a window structure 115. The window structure 115 connects to the optical deflection structure 130 by way of sidewalls 116.

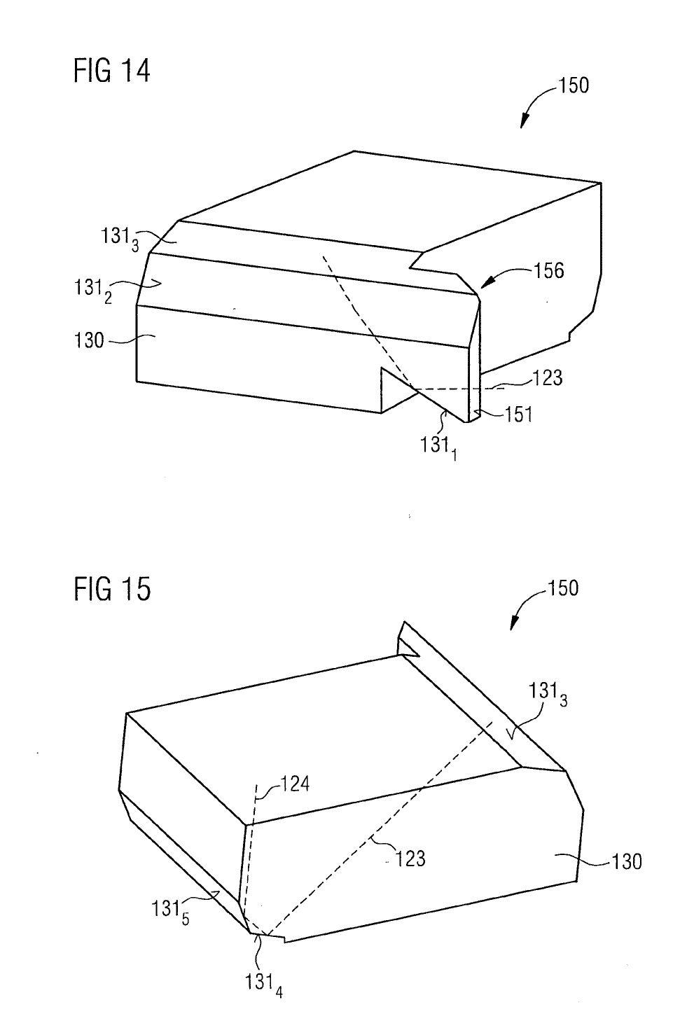

FIG. 14 shows a further optical component 150 comprising an optical deflection structure 130 that defects the laser beam 123 by a plurality of internal reflections. The laser beam 123 enters the optical deflection structure 130 via the input face 151 and reflected at a first reflection face 131₁ in the direction of a second reflection face 131₂ arranged thereover. The second reflection face 131₂ deflects the laser beam 123 to a third reflection face 131₃. As becomes clear from FIG. 15 that shows the optical component 150 of FIG. 14 from the opposite direction, the third reflection face 131₃ reflects the laser beam 123 in the direction of a fourth reflection face 131₄, which is situated in a lower portion of the optical deflection structure 130. By way of the fourth reflection face 131₄, the laser beam 123 is deflected upward in the direction of the surface normal of the assembly face onto a fifth reflection face 131₅, which now reflects the laser beam 123 into the desired vertical direction. As a result of the special arrangement of the reflection faces 131₁ to 131₅, a rotation of the divergence axes of the laser beam 123 is additionally achieved in addition to the deflection of the laser beam 123 from a horizontal direction into a vertical direction. In particular, the laser beam 123 is rotated by 90° after the third reflection. The originally vertically aligned axis of greatest divergence thus extends parallel to the assembly plane. In such an arrangement, there can be a relatively large expansion or fanning of the laser beam 123 within the optical component 150, even in a restricted height of the optical deflection structure 130. Rotation of the axes of divergence of the laser beam 123 by reflection and light refraction are respectively represented by ellipses in the figures.

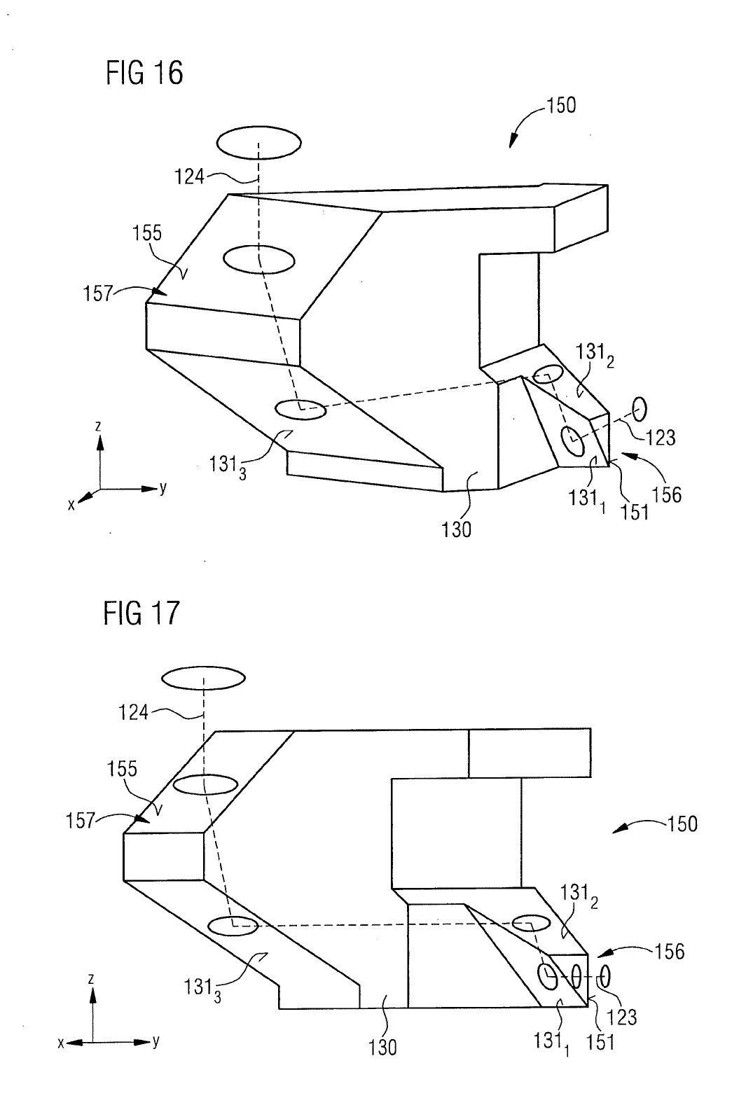

FIG. 16 shows a further optical component 150 with an optical deflection structure 130 in which a rotation of the axes of divergence of the laser beam 123 through 90° is achieved by a plurality of internal reflections. The laser beam 123 enters into the optical component 150 via an input face 151 configured in the form of a refractive window 156 and, in particular, in the form of a Brewster window. In the process, the laser beam 123 is deflected upwardly in the direction of a second reflection face 131₂ by a first reflection face 131₁. The second reflection face 131₂ steers the laser beam 123 onto a third reflection face 131₃ arranged at the opposite side of the optical component 150. At the third reflection face 131₃, the laser beam 123 is deflected into an upward direction onto an emission face 155 configured in the form of a refractive window 157. The emission face 155 is tilted in relation to the direction of propagation of the laser beam 123 such that the laser beam 123 is refracted into the desired vertical direction parallel to the surface normal of the assembly face by the refraction occurring at the emission face. The emission face 155 is preferably configured as a Brewster window as a result of which reflections in the principal polarization direction of the laser radiation are reduced and consequently the electro-optic efficiency of the laser module 100 is increased.

FIG. 17 shows the optical component 150 of FIG. 16 in another perspective representation. What becomes clear here is that the laser beam 123 extends substantially horizontally between the second reflection face 131₂ and the third reflection face 131₃, with its axes of divergence already having been rotated through 90° by the preceding reflections at the two reflection faces 131₁, 131₂.

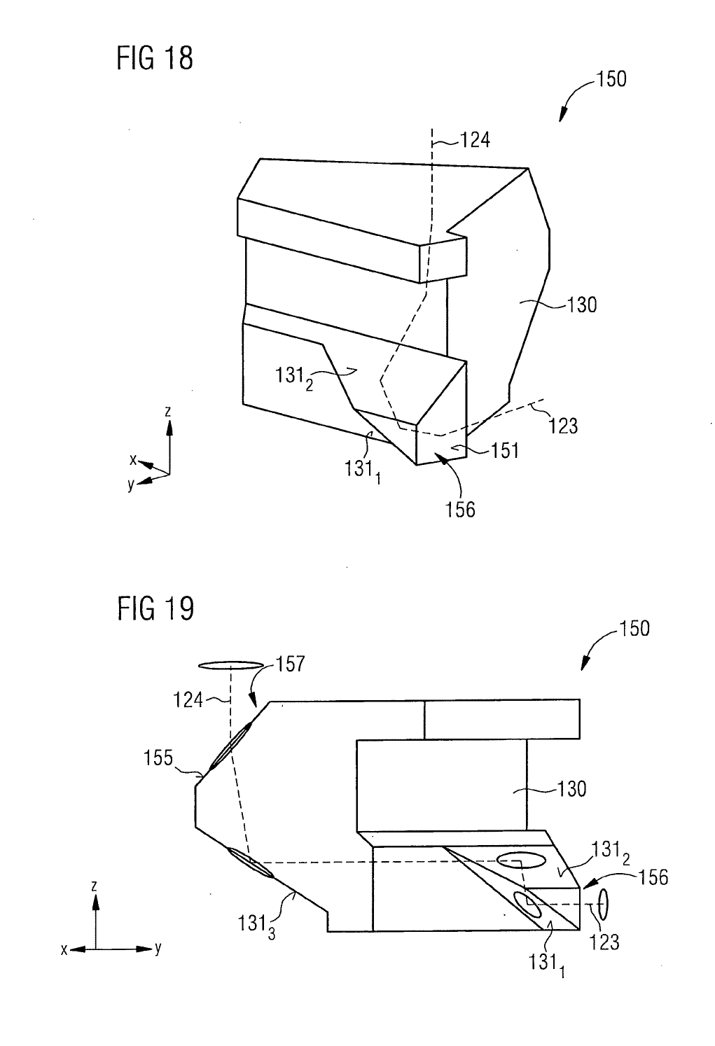

FIG. 18 shows a further perspective illustration of the optical component 150 from FIGS. 16 and 17. What becomes clear here is that the laser beam 123 strikes the input face 151 in an inclined manner, and so there already is refraction of the laser beam 123 at the respective interface.

FIG. 19 shows a further perspective representation of the optical component 150 from FIGS. 16, 17 and 18. What becomes clear here is that the laser beam 121 is refracted in the direction of the surface normal of the assembly face at the emission face 155 that is configured as a refractive window 157.

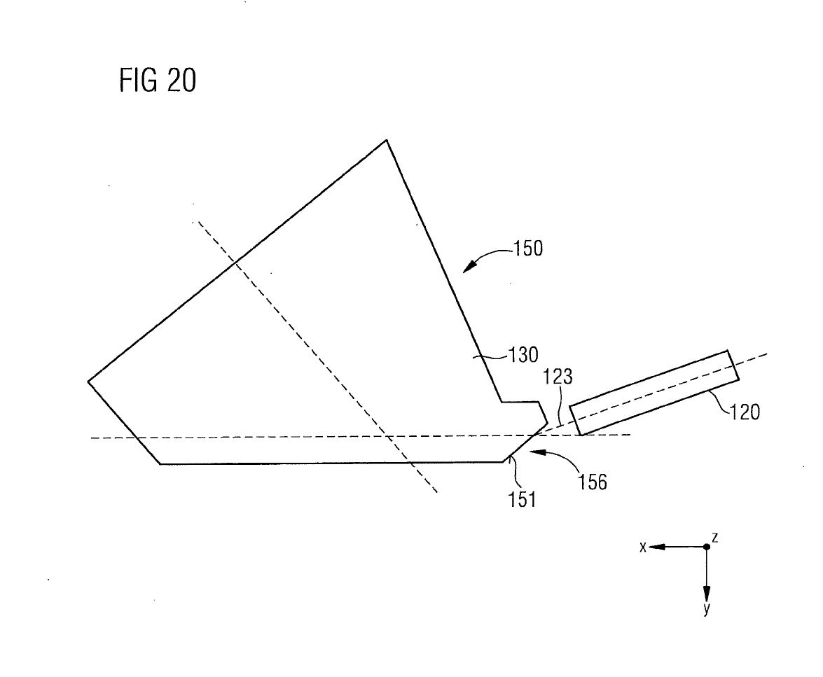

FIG. 20 shows a plan view of the optical component 150 shown in FIGS. 16 to 19. What becomes clear here is the arrangement of the optical component 150 in relation to the laser diode 120. Thus, what is identifiable herefrom is that the laser radiation 123 strikes the input face 151 that is configured as a diffractive window 156 from an oblique direction.

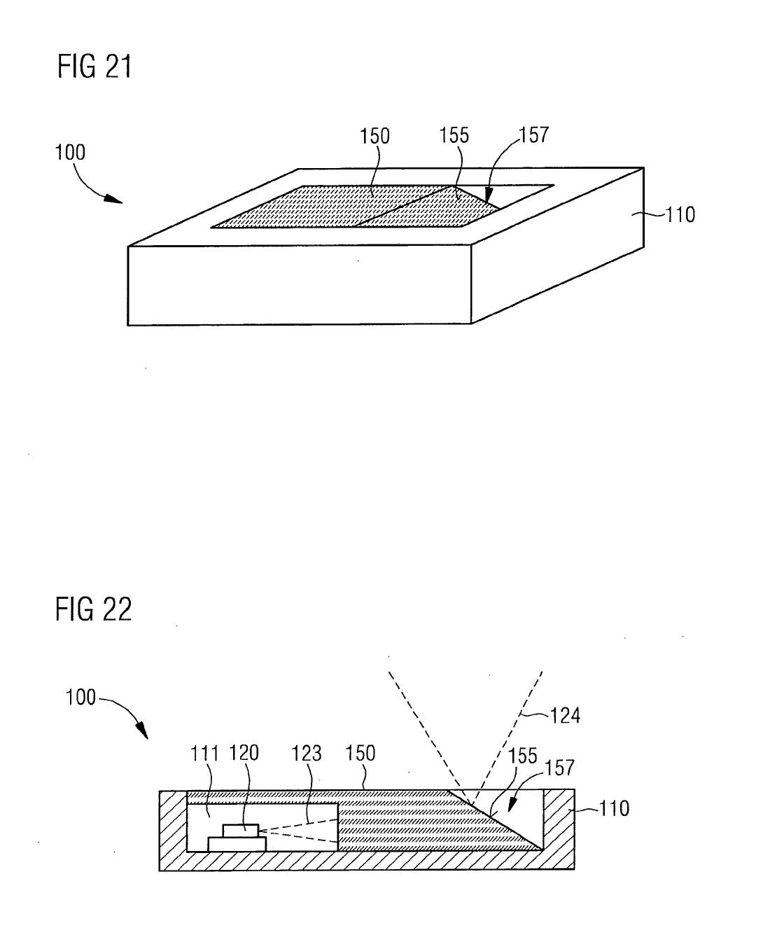

Finally, FIGS. 21 and 22 show a possible design of the laser module 100 with an optical component 150, which has a diffractive emission window 157. As is clear from FIG. 21, the optical component 150 is arranged in a housing cavity formed by lateral walls. FIG. 22 shows a cross section through the laser module 100 from FIG. 21. What is clear here is that the optical component 150 closes off the cavity 111 of the housing 110 with the laser diode 120 arranged therein in a lid-like manner. The light radiation 123 emitted by the laser diode 120 in a horizontal direction extending substantially parallel to the assembly plane is deflected in the optical component 150 by reflection and light refraction into a vertical direction extending substantially parallel to the surface normal of the assembly face.

Use is made of an optical component substantially transparent to the employed laser radiation and suitable for withstanding the temperatures occurring in a standard SMT reflow process without substantial impairment of form and function. The element is specifically formed such that the laser beam is deflected such that the beam axis is emitted from the laser module parallel to the surface normal of the assembly plane. Deflection of the beam is preferably brought about by the effect of total internal reflection (TIR) at a surfaces of the optical component. Alternatively, the corresponding surfaces can also be coated to achieve the reflection. To ensure that beams with a high divergence can also be deflected sufficiently strongly by the TIR effect, the optical component can be formed such that the beam is preferably reflected by total internal reflection at a plurality of surfaces.

Additionally, it is possible that the input and/or emission faces of the optical component are configured as Brewster windows. The relevant faces are tilted through a certain angle, the so-called Brewster angle, in relation to the beam such that the reflection of the present polarization direction at the interface is reduced or completely suppressed by the Brewster effect.

Further, it is also possible to tilt the surface normal of the input face in relation to the beam axis such that the laser beam at the input face is refracted in the direction of the surface normal of the assembly plane. As shown schematically in FIG. 10, this can bring about the deflection of the beam in the desired vertical direction by only one internal reflection.

In a side-emitting semiconductor laser 120, the emitted laser beam 123 has, as a rule, a greater divergence in the vertical direction that is parallel to the surface normal of the assembly plane than in the horizontal direction that is parallel to the assembly plane. Therefore, the direction of maximum beam divergence can be tilted by successive reflections at two orthogonal mirror planes to be substantially parallel to the assembly face or the assembly plane of the laser diode 120.

Moreover, it is possible to guide the laser beam downward in the direction of the substrate in at least one portion of the optical component. First, this facilitates a reduction in the installation height of the optical component 150 and hence of the laser module 100. Further, this can increase the path of the laser beam 123 within the optical component 150 to obtain greater expansion or fanning of the laser beam 123 within the optical component 150. The beam can also be guided in an optical waveguide 134 and thus expanded further without this leading to a greater height of the laser module 100. Subsequently, the laser beam 123 can be made to be parallel to the surface normal of the assembly plane with the aid of further mirror faces and it can leave the module.

Further, the optical component can be integrated in monolithic fashion into a housing. These housings preferably also provide a suitable attachment point for a pick & place tool. By way of example, such a component can be produced cost-effectively in large numbers by a plastics injection molding method.

The examples described in conjunction with the figures are preferably a laser module for time-of-flight applications. Such a laser module uses a semiconductor laser diode operated in a pulse mode. In principle, the optical component 150 can also be applied to laser modules operated in the continuous wave mode.

Even though our modules are illustrated more closely and described in detail by preferred examples, this disclosure is not restricted by the examples and other variations can be derived therefrom by those skilled in the art without departing from the scope of protection of the appended claims.

This application claims priority of DE 10 2016 107 715.1, the subject matter of which is incorporated herein by reference.

1-22. (canceled)

23. A laser module comprising:
a housing with a cavity and a window opening,
a side-emitting semiconductor laser diode, arranged in the cavity that emits light radiation in the form of a laser beam,
an optical deflection structure that deflects the laser beam, emitted by the semiconductor laser diode, in a direction of the window opening, and
an optical output coupling structure arranged in the region of the window opening to output couple the laser beam in a defined direction and/or with a defined emission profile,
wherein the optical deflection structure and the optical output coupling structure are configured in one piece in the form of a shared optical component.

24. The laser module according to claim 23, wherein the optical output coupling structure is at least one of:
configured as a diffractive optical element that produces a laser beam with a defined emission profile, and
configured as a diffractive window.

25. The laser module according to claim 23, wherein the optical component is configured as a solid prism.

26. The laser module according to claim 25, wherein the optical component comprises an input facet facing the semiconductor laser diode, said input facet being equipped with an antireflection coating.

27. The laser module according to claim 24, wherein the optical component is configured to be hollow such that the optical deflection structure and the diffractive optical element connect to one another via sidewalls of the optical component.

28. The laser module according to claim 27, wherein the diffractive optical element is equipped with an antireflection coating on the input side.

29. The laser module according to claim 23, wherein the optical deflection structure comprises a face reflective for the light radiation emitted by the semiconductor laser diode.

30. The laser module according to claim 29, wherein the reflective face of the optical deflection structure comprises a coating made of a metallic or dielectric material.

31. The laser module according to claim 29, wherein the reflective face of the optical deflection structure is arranged at an angle to the semiconductor laser diode at which the deflection of the laser beam, emitted by the semiconductor laser diode, is effected in the direction of the window opening, substantially by total internal reflection.

32. The laser module according to claim 23, further comprising a photodiode arranged downstream of the optical deflection structure in the emission direction of the semiconductor laser diode, said photodiode monitoring the correct assembly position of the optical component in the housing.

33. The laser module according to claim 32, further comprising deactivation electronics that deactivate the semiconductor laser diode as soon as the photodiode registers a deviation from the correct assembly position of the optical component.

34. The laser module according to claim 23, further comprising a driver circuit that operates the semiconductor laser diode.

35. The laser module according to claim 34, wherein the driver circuit is configured to operate the semiconductor laser diode in a pulsed mode of operation.

36. The laser module according to claim 23, wherein the optical component is at least one of:
formed from a plastics material, and
configured as an injection molded part.

37. The laser module according to claim 23, wherein the optical deflection structure comprises at least two reflection faces that deflect the laser beam.

38. The laser module according to claim 37, wherein at least a part of the reflection faces is configured to deflect the laser beam by total internal reflection.

39. The laser module according to claim 37, wherein the reflection faces are arranged in relation to the laser beam, emitted by the laser diode such that a first divergence axis of the laser beam, initially extending substantially perpendicular to an assembly plane, is rotated to be substantially parallel to the assembly plane.

40. The laser module according to claim 23, wherein the optical deflection structure comprises an input face to input couple the laser beam and an emission face to output couple the laser beam, and at least one of the faces is configured as a Brewster window for the laser beam striking thereon.

41. The laser module according to claim 23, wherein the optical deflection structure comprises an optical waveguide structure configured to guide the laser beam within the optical deflection structure by means of total internal reflection.

42. An optical component for the laser module according to claim
